(19) United States
(12) Patent Application Publication
(10) Pub. No.: US 2012/0262204 A1
(43) Pub. Date: Oct. 18, 2012

(54) DRIVER CIRCUIT HAVING AN INSULATED GATE FIELD EFFECT TRANSISTOR FOR PROVIDING POWER

(75) Inventor: Kaoru Yanase, Kanagawa-ken (JP)

(73) Assignee: KABUSHIKI KAISHA TOSHIBA, Tokyo (JP)

(21) Appl. No.: 13/421,091

(22) Filed: Mar. 15, 2012

(30) Foreign Application Priority Data
Apr. 13, 2011 (JP) 2011-088888

(51) Int. Cl. H03K 3/00

(52) U.S. Cl. 327/108

(57) ABSTRACT

In one embodiment, a transistor is connected between a power supply terminal and an output terminal. One end of a first resistor is connected to a gate of the transistor. The other end of the first resistor is connected to a gate voltage terminal. One end of a second resistor is connected to the gate voltage terminal. One end of a first switch is connected to the other end of the second resistor. The first switch is controlled by a control signal controlling the transistor. One end of a second switch is connected to the other end of the first resistor. The other end of the second switch is connected to the output terminal. The second switch is controlled by a signal outputted from the one end of the first switch.

### CROSS-REFERENCE TO RELATED APPLICATION

This application is based upon and claims the benefit of priority from the prior Japanese Patent Application No. 2011-88888, filed on Apr. 13, 2011, the entire contents of which are incorporated herein by reference.

### FIELD

Embodiments described herein relate generally to a driver circuit having an insulated gate field effect transistor for providing power.

### BACKGROUND

A driver circuit using a power MOS transistor is known. A power MOS transistor is connected between a supply terminal and an output terminal of a driver circuit, and serves as a switch provided on a higher voltage side. The driver circuit can drive an inductive load which is connected to an output terminal of the power MOS transistor.

A gate capacitance exists between a gate and a source of the power MOS transistor as a parasitic capacitance. A gate oxide film which gives the gate capacitance has a film thickness smaller than an interlayer insulating film. Accordingly, the value of the gate capacitance is larger than a parasitic capacitance given by the interlayer insulating film. As a result, a large amount of electric charges are accumulated in the gate capacitance when the power MOS transistor is turned on by applying a control voltage to the gate.

When the power MOS transistor is turned off, the electric charges accumulated in the gate capacitance need to be discharged promptly in order to shorten switching time.

A protective resistor and a negative voltage suppression resistor may be inserted in a discharge path from a gate capacitance. The protective resistor protects a gate of a power MOS transistor. The negative voltage suppression resistor suppresses a negative voltage due to a back electromotive force which is generated by an inductive load when the power MOS transistor is turned off. The discharge time period of the gate capacitance is determined by a CR time constant which is defined by a capacitance value C of the gate capacitance, and a resistance value R obtained based on the protective resistor and the negative voltage suppression resistor. Accordingly, when the resistance value R decreased, the discharge time period is shortened. However, the resistance value R cannot be set below a predetermined value because the resistors need to fulfill original purposes of insertion. From the reason, it is not possible to reduce the CR time constant which determines the discharge time period for the gate capacitance.

Such a driver circuit may have difficulty in shortening a switching time period when a power MOS transistor is turned off.

### DETAILED DESCRIPTION

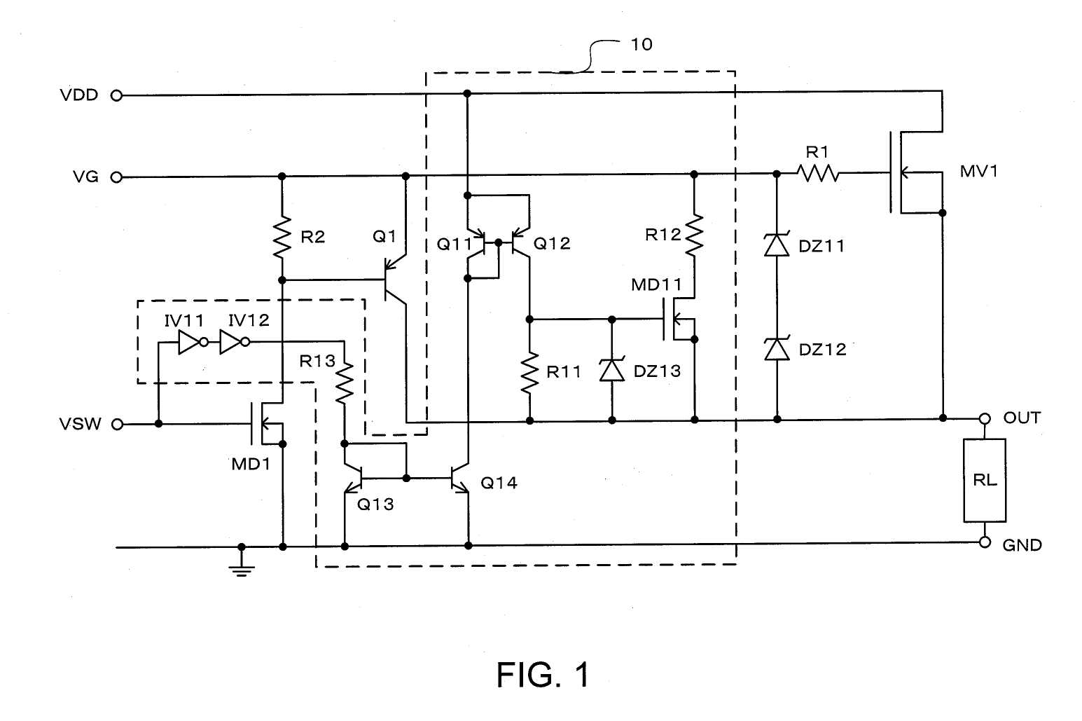

FIG. 1 is a circuit diagram showing a configuration of a driver circuit according to an embodiment of the invention;

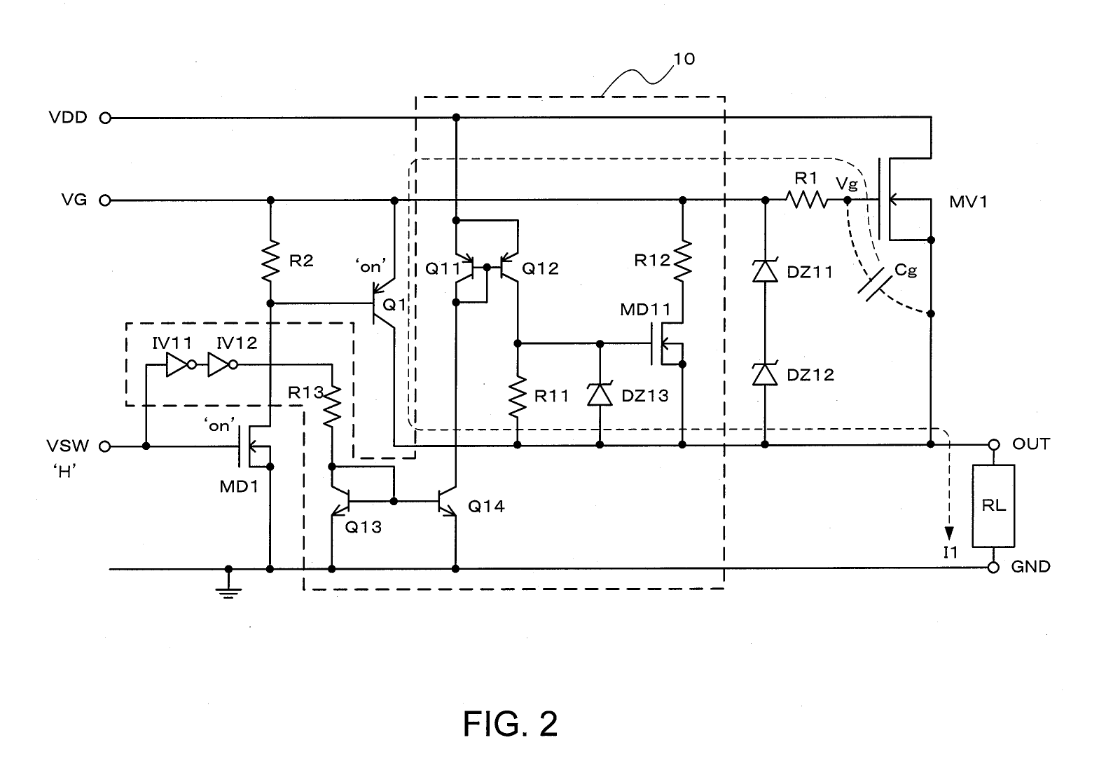

FIG. 2 is a view showing a discharge current path from a gate capacitance when a MOS transistor for providing power is turned off in the driver circuit;

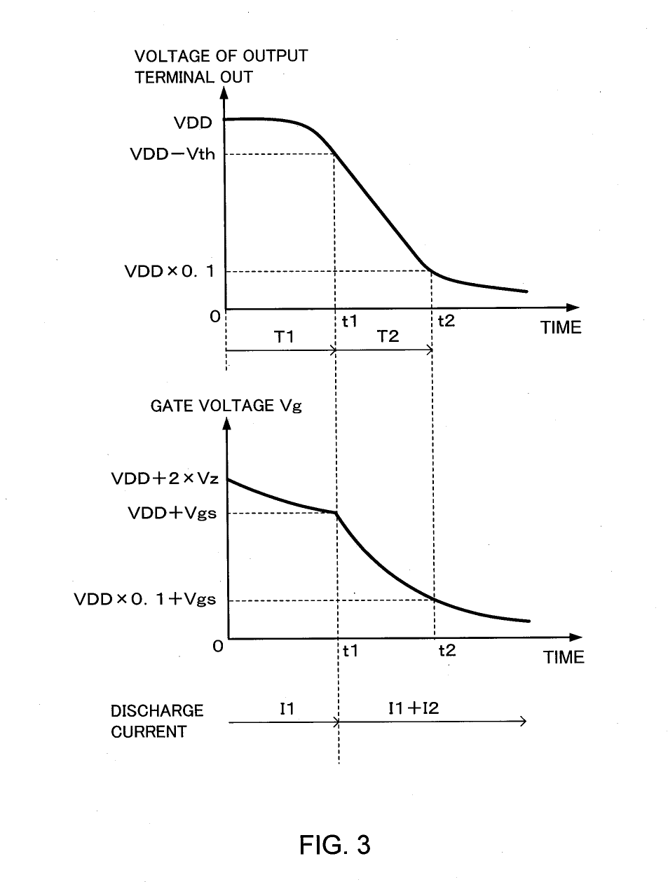

FIG. 3 shows examples of an output voltage waveform and a gate voltage waveform respectively of the MOS transistor when the MOS transistor is turned off;

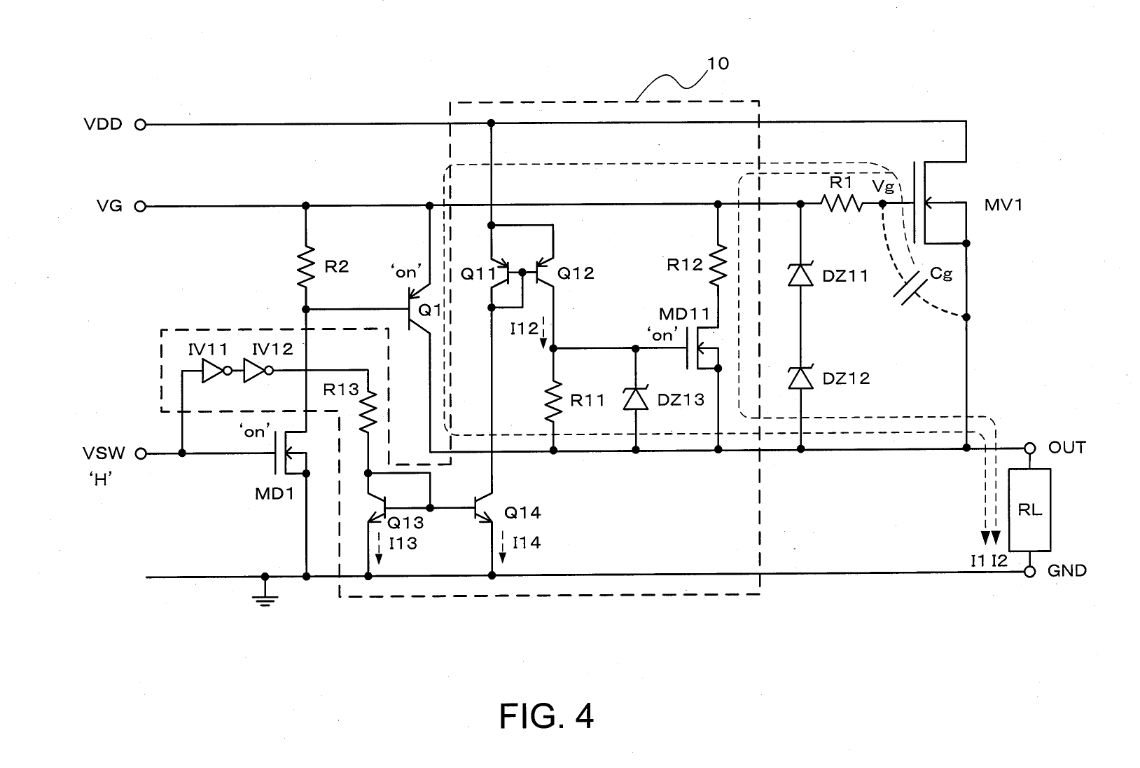

FIG. 4 is a view showing another discharge current path from the gate capacitance when the MOS transistor is turned off, and

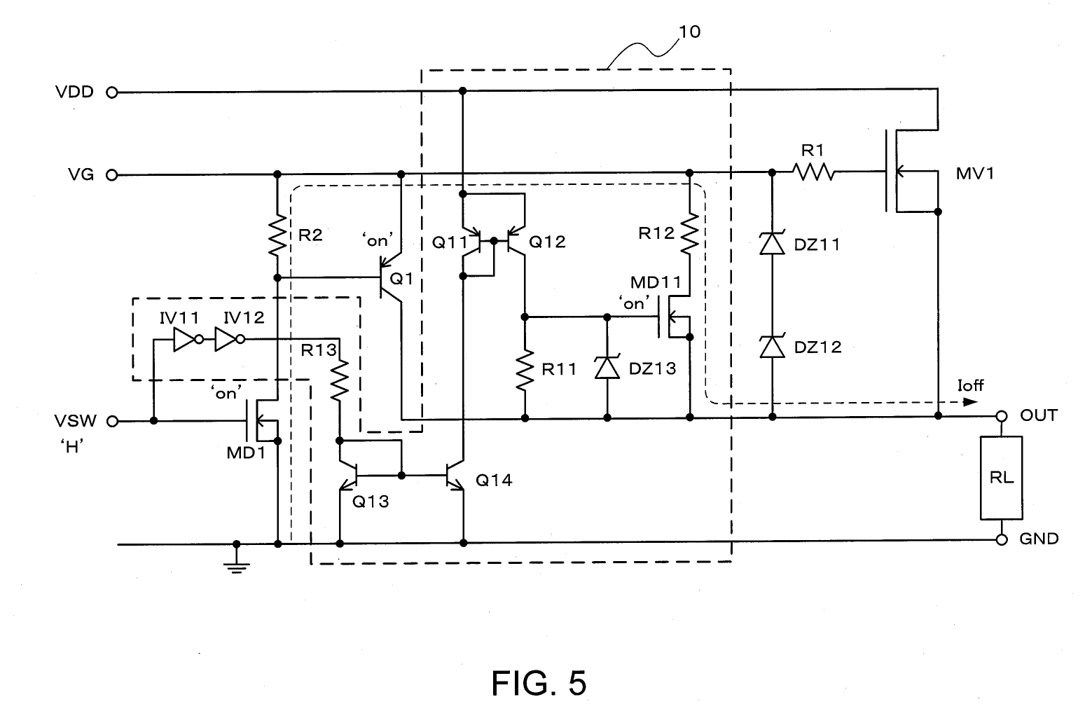

FIG. 5 is a view showing a path of a current flowing caused by a back electromotive force of an inductive load when the MOS transistor is turned off.

### DETAILED DESCRIPTION

According to one embodiment, a driver circuit is provided. The driver circuit has a first field effect transistor, first and second resistors and first and second switches.

The first field effect transistor is connected between a power supply terminal and an output terminal. One end of the first resistor is connected to a gate of the first field effect transistor. The other end of the first resistor is connected to a gate voltage terminal. The second resistor has one end connected to the gate voltage terminal. One end of the first switch is connected to the other end of the second resistor. The other end of the first switch is connected to a ground terminal. The first switch is controlled by a control signal controlling the first field effect transistor. One end of the second switch is connected to the other end of the first resistor. The other end of the second switch is connected to the output terminal. The second switch is controlled by a signal outputted from the one end of the first switch.

Hereinafter, a further embodiment will be described with reference to the drawings.

In the drawings, the same reference numerals denote the same or similar portions respectively.

FIG. 1 is a circuit diagram showing a driver circuit according to the embodiment.

The driver circuit shown in FIG. 1 is provided with a MOS transistor MV1 i.e. a power MOS transistor for providing power, a resistor R1 i.e. a first resistor, a resistor R2 i.e. a second resistor, an N-channel MOS transistor MD1 i.e. a first switch, and a PNP bipolar transistor Q1 i.e. a second switch. The MOS transistor MV1 is connected between a supply terminal VDD and an output terminal OUT. One end of the resistor R1 is connected to a gate of the MOS transistor MV1 and the other end of the resistor R1 is connected to a gate voltage application terminal VG. One end of the resistor R2 is connected to the gate voltage application terminal VG.

A drain of the MOS transistor MD1 is connected to the other end of the resistor R2. A source of the MOS transistor MD1 is connected to a ground terminal GND. A control signal for controlling on/off of the MOS transistor MV1 is transmitted from a control signal input terminal VSW to a gate of the MOS transistor MD1. The MOS transistor MD1 functions as a switch of which conduction is controlled by the control signal from the control signal input terminal VSW. An emitter of the bipolar transistor Q1 is connected to the other end of the resistor R1. A collector of the bipolar transistor Q1 is connected to the output terminal OUT. A base of the bipolar transistor Q1 is connected to the drain of the MOS transistor MD1. The bipolar transistor Q1 functions as a switch of which conduction is controlled by a signal outputted from the drain of the MOS transistor MD1. The driver circuit drives an inductive load RL connected to the output terminal OUT.

Zener diodes DZ11, DZ12 are connected in series between the gate voltage application terminal VG and the output terminal OUT. The Zener diodes DZ11, DZ12 are limiters for preventing a gate voltage of the MOS transistor MV1 from exceeding a predetermined value.

Further, the driver circuit of the embodiment is provided with an OFF detection circuit 10 to detect that the MOS transistor MV1 is turned off. The OFF detection circuit 10 includes inverters IV11, IV12, NPN bipolar transistors Q11 to Q14, resistors R11 to R13, an N-channel MOS transistor MD11, and a Zener diode DZ13.

The inverters IV11, IV12 are connected in series between the control signal input terminal VSW and one end of the resistor R13. An emitter of the transistor Q11 is connected to the supply terminal VDD. A collector and a base of the transistor Q11 are connected to a collector of the transistor Q14. An emitter of the transistor Q12 is connected to the supply terminal VDD, and a base of the transistor Q12 is connected to the base of the transistor Q11. A collector of the transistor Q12 is connected to one end of the resistor R11. An emitter of the transistor Q13 is connected to the ground terminal GND. A collector and a base of the transistor Q13 are connected to the other end of the resistor R13. An emitter of the transistor Q14 is connected to the ground terminal GND and a base of the transistor Q14 is connected to the base of the transistor Q13.

The other end of the resistor R11 is connected to the ground terminal GND. One end of the resistor R12 is connected to the gate voltage application terminal VG. The other end of the resistor R12 is connected to a drain of the MOS transistor MD11. A source of the MOS transistor MD11 is connected to the output terminal OUT. A gate of the MOS transistor MD11 is connected to the one end of the resistor R11 and one end of the Zener diode DZ13. The other end of the Zener diode DZ13 is connected to the output terminal OUT.

A drain of the MOS transistor MV1 is connected to the supply terminal VDD. The MOS transistor MV1 becomes conductive when a positive voltage equal to or above a threshold voltage Vth is applied to the gate of the MOS transistor MV1. The MOS transistor MV1 supplies a drive current to the inductive load RL connected to the output terminal OUT that is a source of the MOS transistor MV1.

The gate voltage controlled by the control signal from the control signal input terminal VSW is applied from the gate voltage application terminal VG to the gate of the MOS transistor MV1 through the resistor R1.

The resistor R1 is a protective resistor for preventing an abnormal current from flowing into the gate of the MOS transistor MV1.

The resistor R2 and the MOS transistor MD1 are connected in series between the gate voltage application terminal VG and the ground terminal GND.

Operations for turning on and off the MOS transistor MV1 will be described below.

A control signal from the control signal input terminal VSW is set to a ‘L’ (low) level when the MOS transistor MV1 is turned on.

Further, when the control signal is set to the ‘L’ level, a higher-level positive voltage is inputted to the gate voltage application terminal VG.

The MOS transistor MD1 is turned off when the control signal is set to the ‘L’ level, and a level at the drain of the MOS transistor MD1 becomes equal to the level of the positive voltage inputted to the gate voltage application terminal VG, substantially.

The PNP bipolar transistor Q1 is also turned off as the drain of the MOS transistor MD1 becomes substantially equal to the level of the positive voltage inputted to the gate voltage application terminal VG.

As a consequence, the higher-level positive voltage inputted to the gate voltage application terminal VG is applied to the gate of the MOS transistor MV1, and the MOS transistor MV1 is turned on accordingly.

When the MOS transistor MV1 is turned on, the voltage at the output terminal OUT becomes equal to VDD. In this process, a gate voltage Vg of the MOS transistor MV1 is limited to Vg=VDD+2×Vz, assuming that a Zener voltages of the Zener diodes DZ11, DZ12 is equal to Vz.

Gate capacitance Cg that is a parasitic capacitance is formed between the gate of the MOS transistor MV1 and the source of the MOS transistor MV1 i.e. the output terminal OUT. Accordingly, when the MOS transistor MV1 is turned on, electric charges corresponding to a potential difference between the gate voltage Vg and the output voltage VDD are accumulated in the gate capacitance Cg.

Then, the control signal from the control signal input terminal VSW is set to a ‘H’ (high) level when the MOS transistor MV1 is turned off. Moreover, when the control signal VSW is set to the ‘H’ level, the gate voltage application terminal VG is short-circuited to the ground terminal GND.

In this process, the electric charges accumulated in the gate capacitance Cg need to be promptly discharged in order to turn off the MOS transistor MV1 quickly. In the embodiment, the PNP bipolar transistor Q1 is used as a discharge path for this purpose.

A discharge operation of the gate capacitance Cg will be described with reference to FIG. 2 to FIG. 4.

As shown in FIG. 2, the MOS transistor MD1 is turned on when the control signal from the control signal input terminal VSW is set to the ‘H’ level. In this way, the voltage level at the drain of the MOS transistor MD1 becomes equal to the ground level so that the PNP bipolar transistor Q1 is also turned on.

When the PNP bipolar transistor Q1 is turned on, a discharge current I1 flows from the gate capacitance Cg through the PNP bipolar transistor Q1. As the discharge current I1 flows, the gate voltage Vg of the MOS transistor MV1 drops and the voltage at the output terminal OUT drops as well.

The upper portion of FIG. 3 shows the change in the voltage at the output terminal OUT when the MOS transistor MV1 is turned off, and The lower portion of FIG. 3 shows the change in the gate voltage Vg at that moment.

The discharge through the PNP bipolar transistor Q1 continues, until the gate voltage Vg of the MOS transistor MV1 drops to the threshold voltage Vth and the voltage at the output terminal OUT becomes equal to VDD−Vth at time t1 shown in the upper portion of FIG. 3. As shown in the lower portion of FIG. 3, the gate voltage Vg of the MOS transistor MV1 at the time t1 can be expressed as Vg=VDD+Vgs. In the expression, Vgs means a gate-source voltage of the MOS transistor MV1.

Assuming that the start time of the discharge is 0, the gate voltage Vg that is a terminal voltage of the gate capacitance Cg, is deemed to have dropped from VDD+2×Vz to VDD+Vgs during a discharge period T1 down to the time t1. When R1 denotes a resistance value of the resistor R1 and Cg denotes a capacitance value of the gate capacitance Cg, the change in the voltage i.e. a discharge voltage can be expressed by the following formulae.

VDD+Vgs=(VDD+2×Vz)·exp(−T1/Cg·R1) (1)

(VDD+Vgs)/(VDD+2×Vz)=exp(−T1/Cg·R1) (2)

The following formula is obtained by taking the natural logarithm of both sides of the formula (2):

ln{(VDD+Vgs)/(VDD+2×Vz)}=−T1/Cg·R1 (3)

The discharge period T1 is obtained from the formula (3) as follows.

$$\begin{matrix}T 1 = - Cg \cdot R 1 \cdot ln \{ ( VDD + Vgs ) / ( VDD + 2 \times Vz ) \} \\ = Cg \cdot R 1 \cdot ln \{ ( VDD + 2 \times Vz ) / ( VDD + Vgs ) \}\end{matrix} \qquad ( 4 )$$

Then, the OFF detection circuit 10 starts an operation when the gate voltage Vg of the MOS transistor MV1 drops to the threshold voltage Vth so that the drive current stops flowing to the inductive load RL.

In the OFF detection circuit 10, when the control signal from the control signal input terminal VSW is set to the ‘H’ level, a current I13 starts to flow into the transistor Q13 which is driven by the inverters IV12, IV13 as shown in FIG. 4. As the current I13 flows, a current I14 flows into the transistor Q14 which constitutes a current mirror circuit together with the transistor Q13. Resultantly, current flows into the transistor Q11 to which the transistor Q14 is connected so that a current I12 also begins to flow into the transistor Q12 which constitutes a current mirror circuit together with the transistor Q11.

When the current I12 flows into the transistor Q12, a voltage arises at the one end of the resistor R11 so that the MOS transistor MD11 is turned on. The MOS transistor MD11 is connected to the other end of the resistor R1 through the resistor R12. Accordingly, when the MOS transistor MD11 is turned on, a discharge current 12 begins to flow from the gate capacitance Cg through the resistor R1 and the resistor R12. In other words, as shown in FIG. 3B, from the time t1, the number of discharge paths is increased, and the discharge current equivalent to I1+I2 begins to flow.

A gate voltage of the MOS transistor MD11 is suppressed to a Zener voltage of the Zener diode DZ13 or below.

As shown in the upper portion of FIG. 3, assuming that time t2 when the voltage at the output terminal OUT becomes equal to VDD×0.1 is defined as ending time of a trailing edge of the voltage at the output terminal OUT, the gate voltage Vg of the MOS transistor MV1 at the time t2 can be expressed as Vg=VDD×0.1+Vgs.

Assuming that a time period from the time t1 to the time t2 is a discharge period T2, a relation between the gate voltage (Vg=VDD+Vgs) at the time t1 and the gate voltage i.e. a discharge voltage at the time t2 can be expressed as follows.

VDD×0.1+Vgs=(VDD+Vgs)·exp(−T2/Cg·R1) (5)

The discharge period T2 can be obtained as described below by applying the method of obtaining the formula (4) similarly.

T2=Cg·R1·ln{(VDD+Vgs)/(VDD×0.1+Vgs)} (6)

Accordingly, assuming the time period until switching off the MOS transistor MV1 is defined as Toff, the value Toff is calculated as follows.

$$\begin{matrix}Toff = T 1 + T 2 \\ = Cg [ \begin{matrix}R 1 \cdot ln \{ ( VDD + 2 \times Vz ) / ( VDD + Vgs ) \} + \\ R 1 \cdot ln \{ ( VDD + Vgs ) / ( VDD \times 0.1 + Vgs ) \}\end{matrix} ]\end{matrix} \qquad ( 7 )$$

Since the PNP bipolar transistor Q1 is provided as a discharge path from the gate capacitance Cg in the embodiment, involve the resistor R2 does not involve the formula (7) representing the time period Toff until switching off the MOS transistor MV1.

On the other hand, the resistor R2 and the MOS transistor MD1 serve as a sole discharge path, when any discharge path using the PNP bipolar transistor Q1 is not employed. Assuming that R2 and R12 denote resistance values of the resistors R2, R12, respectively, the time period ToffA of switching off the MOS transistor MV1 in this case can be expressed as follows.

$$ToffA = Cg [ \begin{matrix}( R 1 + R 2 ) \cdot ln \{ ( VDD + 2 \times Vz ) / ( VDD + Vgs ) \} + \\ ( R 1 + R 2 // R 12 ) \cdot ln \{ ( VDD + Vgs ) / ( VDD \times 0.1 + Vgs ) \}\end{matrix} ] \qquad ( 8 )$$

As apparent from a comparison between the formula (8) and the formula (7), in the formula (7) of the embodiment which represents the time period Toff of switching off the MOS transistor MV1, the resistance value of the resistor R2 is not included in the CR time constant relating to discharge characteristic. The time period until switching off the MOS transistor MV1 is reduced accordingly.

It is possible to reduce the value ToffA in the formula (8) when the resistance value of the resistor R2 can be set smaller. However, the resistor R2 is a negative voltage suppression resistor for suppressing a negative voltage at the output terminal OUT. The negative voltage is required for maintaining an off-state of the MOS transistor MV1 when the transistor MV1 is turned off. As a consequence, reduction in the resistance value of the resistor R2 causes a problem of an increase in the negative voltage which is required for maintaining the off-state of the MOS transistor MV1.

A relation between the resistance value of the resistor R2 and the negative voltage at the output terminal OUT required for maintaining the off-state of the MOS transistor MV1 will be described below.

As shown in FIG. 5, when the negative voltage arises at the output terminal OUT as the MOS transistor MV1 is turned off, an off-current Ioff flows from the ground terminal GND towards the output terminal OUT. A path of the flow of the off-current Ioff is defined as a path from the ground terminal GND, through the MOS transistor MD1, the resistor R2, the resistor R12, and the MOS transistor MD11, to the output terminal OUT.

Accordingly, assuming that on-resistance values of the MOS transistors MD1, MD11 are Ron1, Ron2 and an output voltage at the output terminal OUT is Vout, respectively, the off-current Ioff can be expressed as follows.

Ioff=(GND−Vout)/(Ron1+R2+R12+Ron2) (9)

Accordingly, the gate-source voltage Vgs of the MOS transistor MV1 can be expressed as follows.

$$\begin{matrix}Vgs = Ioff \times ( R 12 + R on 2 ) \\ = - Vout \times ( R 12 + R on 2 ) / ( R on 1 + R 2 + R 12 + R on 2 )\end{matrix} \qquad ( 10 )$$

In order to maintain the off-state of the MOS transistor MV1, the gate-source voltage Vgs needs to be lower than the threshold Vth. Thus, the following inequality should be met.

−Vout×(R12+Ron2)/(Ron1+R2+R12+Ron2)<Vth (11)

It is apparent from the formula (11) that the gate-source voltage Vgs of the MOS transistor MV1 can be made smaller by increasing the resistance value of the resistance R2 when the output voltage Vout is constant.

Moreover, it is also apparent that the value of the output voltage Vout required for setting the gate-source voltage Vgs lower than the threshold Vth can be made smaller by increasing the resistance value of the resistance R2.

In the embodiment, the formula (7) for obtaining the time period Toff until switching off the MOS transistor MV1 does not involve the resistor R2 as described previously. Accordingly, even when the resistance value of the resistor R2 is increased in order to reduce the value of the output voltage Vout required for setting the gate-source voltage Vgs lower than the threshold Vth, such an increase does not lead to an increase in the time period until switching off the MOS transistor MV1.

The value of the output voltage Vout is derived from the formula (10) as follows.

Vout=−(Ron1+R2+R12+Ron2)/(R12+Ron2)×Vgs (12)

According to the above-described embodiment, the electric charges accumulated in the gate capacitance Cg are discharged through the PNP bipolar transistor Q1 when the MOS transistor MV1 is turned off. Thus, it is possible to prevent the discharge current from flowing to the resistor R2 which serves as the negative voltage suppression resistor for maintaining the off-state. As a result, the time constant for determining the discharge time period does not involve the resistance value of the resistor R2. Thus, it is possible to shorten the switching time period when the MOS transistor MV1 is turned off.

Since the resistor R2 is not involved in the time period of switching off the MOS transistor MV1, the value of the negative voltage at the output terminal OUT required for maintaining the off-state of the MOS transistor MV1 can be reduced by increasing the resistance value of the resistor R2.

The driver circuit according to the embodiment can shorten the switching time period when the MOS transistor MV1 is turned off.

While a certain embodiment has been described, the embodiment has been presented by way of example only, and is not intended to limit the scope of the invention. Indeed, the novel embodiment described herein may be embodied in a variety of other forms; furthermore, various omissions, substitutions and changes in the form of the embodiment described herein may be made without departing from the spirit of the invention. The accompanying claims and their equivalents are intended to cover such forms or modifications as would fall within the scope and spirit of the invention.

The MOS transistors mentioned above are recited as examples of insulated gate field effect transistors respectively.

What is claimed is:

1. A driver circuit comprising:
a first field effect transistor connected between a power supply terminal and an output terminal;
a first resistor, one end of the first resistor being connected to a gate of the first field effect transistor, the other end of the first resistor being connected to a gate voltage terminal;
a second resistor having one end connected to the gate voltage terminal;
a first switch, one end of the first switch being connected to the other end of the second resistor, the other end of the first switch being connected to a ground terminal, the first switch being controlled by a control signal controlling the first field effect transistor; and
a second switch, one end of the second switch being connected to the other end of the first resistor, the other end of the second switch being connected to the output terminal, the second switch being controlled by a signal outputted from the one end of the first switch.

2. A circuit according to claim 1, further comprising a detection circuit to detect turning-off of the gate field effect transistor, wherein
the detection circuit is provided with a third resistor and a third switch connected in series between the other end of the first resistor and the output terminal, and
the detection circuit turns the third switch on when the detection circuit detects not to flow an output current to the first field effect transistor.

3. A circuit according to claim 1, wherein, the first field effect transistor discharges electric charges accumulated in a parasitic capacitance in a case where the first field effect transistor is controlled to be off.

4. A circuit according to claim 1, wherein when a discharge current flows to the second switch and a discharge voltage of the parasitic capacitance drops to a threshold voltage of the first field effect transistor, the third switch becomes conductive and the discharge current also flows to the third switch.

5. A circuit according to claim 1, wherein the first switch is a second MOS transistor.

6. A circuit according to claim 1, wherein the second switch is a bipolar transistor.

7. A circuit according to claim 2, wherein the third switch is a third MOS transistor.

8. A circuit according to claim 3, wherein the first switch is a second field effect transistor, and the second switch is a bipolar transistor.

9. A circuit according to claim 4, wherein the second switch is a bipolar transistor, and the third switch is a third field effect transistor.

10. A circuit according to claim 1, further comprising a Zener diode connected between the other end of the first resistor and the output terminal.

11. A circuit according to claim 1, wherein the first field effect transistor is a MOS transistor.

12. A circuit according to claim 5, wherein the first field effect transistor and the first switch is MOS transistors respectively.

13. A circuit according to claim 8, wherein the first field effect transistor and the first switch are MOS transistors respectively, and the second switch is a bipolar transistor.

14. A circuit according to claim 9, wherein the second switch is a bipolar transistor, and the first field effect transistor and the third switch are MOS transistors respectively.
